(19) United States
(12) Patent Application Publication
(10) Pub. No.: US 2025/0282993 A1
(43) Pub. Date: Sep. 11, 2025

(54) PHOSPHOR COMPOSITIONS AND DEVICES THEREOF

(71) Applicant: GE Intellectual Property Licensing, LLC, Niskayuna, NY (US)

(72) Inventors: Samuel Joseph Camardello, Ballston Spa, NY (US); James E. Murphy, Niskayuna, NY (US)

(21) Appl. No.: 18/862,301

(22) PCT Filed: Apr. 6, 2023
(86) PCT No.: PCT/US2023/065472

§ 371 Date: Nov. 1, 2024

Related U.S. Application Data
(60) Provisional application No. 63/338,428, filed on May 4, 2022.

(51) Int. Cl. C09K 11/77; C01B 25/45; C09K 11/02; C09K 11/71; H10H 20/851

(52) U.S. Cl. CPC C09K 11/7737; C01B 25/45; C09K 11/025; C09K 11/71; H10H 20/8513; H10H 20/8515; C01P 2002/54; C01P 2002/72; C01P 2006/60

(57) ABSTRACT

A phosphor composition includes a red phosphor material having a red decay rate and a green phosphor material having a green decay rate. The red phosphor material includes a Mn⁴⁺ doped phosphor of Formula I and a Eu³⁺ doped uranium phosphor, and a difference between the red decay rate and the green decay rate is no more than 7 ms, AₓMF_{y}:Mn⁴⁺ (I), wherein A is Li, Na, K, Rb, Cs, or a combination thereof; M is Si, Ge, Sn, Ti, Zr, Al, Ga, In, Sc, Hf, Y, La, Nb, Ta, Bi, Gd, or a combination thereof; x is an absolute value of a charge of the MF_{y} ion; and y is 5, 6 or 7. A device is also provided.

### CROSS REFERENCE TO RELATED APPLICATIONS

This application claims the priority benefit of U.S. Provisional Patent Application Ser. No. 63/338,428 filed May 4, 2022, which is hereby incorporated by reference in its entirety.

### BACKGROUND

The field of the invention relates generally to phosphor compositions and devices, and more particularly to devices and displays presenting good brightness, large color gamut and reduced lag time.

Current display device technology relies on liquid crystal displays (LCDs), which is one of the most widely used flat panel displays for industrial and residential applications. Next-generation devices will have low energy consumption, compact size, and high brightness, requiring larger color gamut coverage. Smaller LEDs, such as mini-LEDs or micro-LEDs, will be needed for next-generation devices. Mini-LEDs have a size of about 100 μm to 0.7 mm and micro-LEDs have sizes smaller than 100 μm. Displays may include miniaturized backlighting arrayed with individual mini-LEDs or micro-LEDs, or displays may be without LCDs and include self-emissive phosphor converted (PC) mini-LEDs or micro-LEDs.

White light can be generated by employing a near-ultraviolet (UV) or blue emitting LED in conjunction with an inorganic phosphor or a blend of inorganic phosphors, such as red-emitting phosphors and green or yellow-green emitting phosphors. The total emission from the phosphor and the LED chip provides a color point with corresponding color coordinates (x and y on the 1931 CIE chromaticity diagram) and correlated color temperature (CCT), and its spectral distribution provides a color rendering capability, measured by the color rendering index (CRI) based on a scale of 100.

Ideally, phosphors employed in blends for display applications will have similar decay times. Mismatches in phosphor decay times between phosphors in a phosphor blend can cause color shifts and can result in display lag, blurring of the display and ghosting.

Some next-generation devices, such as PC micro-LEDs are self-emissive and do not require an LCD. These devices and displays can have faster response times and phosphors with faster decay times are desired. Mismatches between phosphor decay times in devices without LCDs can be more of a concern.

### BRIEF DESCRIPTION

In one aspect, a phosphor composition includes a red phosphor material having a red decay rate and a green phosphor material having a green decay rate, wherein the red phosphor material includes a Mn⁴⁺ doped phosphor of Formula I and a Eu³⁺ doped uranium phosphor, and wherein a difference between the red decay rate and the green decay rate is no more than 7 ms,

AₓMF_{y}:Mn⁴⁺ (I),

wherein A is Li, Na, K, Rb, Cs, or a combination thereof; M is Si, Ge, Sn, Ti, Zr, Al, Ga, In, Sc, Hf, Y, La, Nb, Ta, Bi, Gd, or a combination thereof; x is an absolute value of a charge of the MF_{y} ion; and y is 5, 6 or 7.

In another aspect, a device includes an LED light source optically coupled and/or radiationally connected to a phosphor composition, wherein the phosphor composition includes a red phosphor material having a red decay rate and a green phosphor material having a green decay rate, wherein the red phosphor material includes a Mn⁴⁺ doped phosphor of formula I and a Eu³⁺ doped uranium phosphor, and wherein a difference between the red decay rate and the green decay rate is no more than 7 ms,

AₓMF_{y}:Mn⁴⁺ (I),

wherein A is Li, Na, K, Rb, Cs, or a combination thereof; M is Si, Ge, Sn, Ti, Zr, Al, Ga, In, Sc, Hf, Y, La, Nb, Ta, Bi, Gd, or a combination thereof; x is an absolute value of a charge of the MF_{y} ion; and y is 5, 6 or 7.

### BRIEF DESCRIPTION OF THE DRAWINGS

FIG. 1 is a schematic cross-sectional view of a device, in accordance with one embodiment of the disclosure.

FIG. 2 is a schematic cross-sectional view of a lighting apparatus, in accordance with one embodiment of the disclosure.

FIG. 3 is a schematic cross-sectional view of a lighting apparatus, in accordance with another embodiment of the disclosure.

FIG. 4 is a cutaway side perspective view of a lighting apparatus, in accordance with one embodiment of the disclosure.

FIG. 5 is a schematic perspective view of a surface-mounted device (SMD), in accordance with one embodiment of the disclosure.

FIG. 6 shows the XRD powder pattern for gamma-Ba₂UO₂(PO₄)₂.

FIG. 7 is a spectra graph of emission wavelength (nm) vs. emission intensity for the DU-Red sample and the NFS sample as provided in Example 1.

FIG. 8 is a spectra graph of emission wavelength (nm) vs. emission intensity for the combination of the DU-Red and the NFS samples as provided in Example 1

### DETAILED DESCRIPTION

In the following specification and the claims, reference will be made to a number of terms, which shall be defined to have the following meanings.

The singular forms “a”, “an”, and “the” include plural references unless the context clearly dictates otherwise.

Approximating language, as used herein throughout the specification and claims, may be applied to modify any quantitative representation that could permissibly vary without resulting in a change in the basic function to which it is related. Accordingly, a value modified by a term or terms, such as “about,” “substantially,” and “approximately,” are not to be limited to the precise value specified. In at least some instances, the approximating language may correspond to the precision of an instrument for measuring the value. Here and throughout the specification and claims, range limitations may be combined and/or interchanged, such ranges are identified and include all the sub-ranges contained therein unless context or language indicates otherwise. All references are incorporated herein by reference.

Square brackets in the formulas indicate that at least one of the elements within the brackets is present in the phosphor material, and any combination of two or more thereof may be present, as limited by the stoichiometry of the composition. For example, the formula [Ca,Sr,Ba]₃MgSi₂O₈:Eu²⁺,Mn²⁺ encompasses at least one of Ca,Sr or Ba or any combination of two or more of Ca, Sr or Ba. Examples include Ca₃MgSi₂O₈:Eu²⁺, Mn²⁺; Sr₃MgSi₂O₈:Eu²⁺, Mn²⁺; or Ba₃MgSi₂O₈:Eu²⁺,Mn²⁺ Formula with an activator after a colon “:” indicates that the phosphor composition is doped with the activator. Formula showing more than one activator separated by a “,” after a colon “:” indicates that the phosphor composition is doped with either activator or both activators. For example, the formula [Ca,Sr,Ba]₃MgSi₂O₈:Eu²⁺, Mn²⁺ encompasses [Ca,Sr,Ba]₃MgSi₂O₈:Eu²⁺, formula [Ca,Sr,Ba]₃MgSi₂O₈:Mn²⁺ or formula [Ca,Sr,Ba]₃MgSi₂Og:Eu²⁺ and Mn²⁺.

Devices and displays can employ light emitting diodes (LEDs) to create a white light, which can be generated with a near-ultraviolet (UV) or blue emitting LED in conjunction with a blend of red-emitting phosphors and green or yellow-green emitting phosphors. In a blend of phosphors there can be a mismatch in the decay rates or times of the phosphors and this mismatch can affect displays and may cause blurring, a display lag and ghosting, particularly in faster display devices that are self-emissive and do not require LCDs (liquid crystal displays), such as PC (phosphor converted) micro-LED displays.

Narrow band red-emitting phosphors, such as phosphors based on complex fluoride materials activated by Mn⁴⁺ are desired for their large color gamut and good quantum efficiency properties. The inventors have discovered that a red phosphor material, which includes a complex fluoride material activated by Mn⁴⁺ and a Eu³⁺ doped uranium phosphor, and a green phosphor material minimizes a mismatch in decay times, while maintaining a large color gamut, brightness and good quantum efficiency.

In one aspect, a phosphor composition includes a red phosphor material having a red decay rate and a green phosphor material having a green decay rate, wherein the red phosphor material includes a Mn⁴⁺ doped phosphor of Formula I and a Eu³⁺ doped uranium phosphors, and wherein a difference between the red decay rate and the green decay rate is no more than 7 ms,

AₓMF_{y}:Mn⁴⁺ (I),

wherein A is Li, Na, K, Rb, Cs, or a combination thereof; M is Si, Ge, Sn, Ti, Zr, Al, Ga, In, Sc, Hf, Y, La, Nb, Ta, Bi, Gd, or a combination thereof; x is an absolute value of a charge of the MF_{y} ion; and y is 5, 6 or 7.

The red phosphor material blends a Mn⁴⁺ doped phosphor of Formula I and a Eu³⁺ doped uranium phosphor. The Mn⁴⁺ doped phosphor of formula I is a narrow band red-emitting phosphor based on complex fluoride materials activated by Mn⁴⁺. Suitable red-emitting phosphors based on complex fluoride materials and processes for making the phosphors are described in U.S. Pat. Nos. 7,497,973, 7,648,649, 8,906,724, 8,252,613, 9,698,314, US 2016/0244663, US Publication No. 2018/0163126, and US Publication No. 2020/0369956. The entire contents of each of which are incorporated herein by reference.

The red phosphor material includes Mn⁴⁺ doped phosphors of formula I

Aₓ(MF_{y}):Mn⁺⁴ (I)

wherein A is Li, Na, K, Rb, Cs, or a combination thereof; M is Si, Ge, Sn, Ti, Zr, Al, Ga, In, Sc, Y, La, Nb, Ta, Bi, Gd, or a combination thereof; x is the absolute value of the charge of the (MF_{y}) ion; and y is 5, 6 or 7.

Examples of the red-emitting phosphors of formula I include, but are not limited to, K₂(SiF₆):Mn⁴⁺, K₂(TiF₆):Mn⁴⁺, K₂(SnF₆):Mn⁴⁺, Cs₂(TiF₆):Mn⁴⁺, Rb₂(TiF₆):Mn⁴⁺, Cs₂(SiF₆):Mn⁴⁺, Rb₂(SiF₆):Mn⁴⁺, Na₂(TiF₆):Mn⁴⁺, Na₂(SiF₆):Mn⁴⁺, Na₂(ZrF₆):Mn⁴⁺, K₃(ZrF₇):Mn⁴⁺, K₃(BiF₇):Mn⁴⁺, K₃(YF₇):Mn⁴⁺, K₃(LaF₇):Mn⁴⁺, K₃(GdF₇):Mn⁴⁺, K₃(NbF₇):Mn⁴⁺, and K₃(TaF₇):Mn⁴⁺.

The amount of activator Mn incorporation in the Mn⁴⁺ doped phosphors (referred to as Mn %) improves color conversion. Increasing the amount of Mn % incorporation improves color conversion by increasing the intensity of the red emission, maximizing absorption of excitation blue light and reducing the amount of unconverted blue light or bleed-through of blue light from a blue LED.

In one embodiment, the red-emitting Mn⁴⁺ doped phosphor has a Mn loading or Mn % of at least 1 wt %. In another embodiment, the red-emitting phosphor has a Mn loading of at least 1.5 wt %. In another embodiment, the red-emitting phosphor has a Mn loading of at least 2 wt %. In another embodiment, the red-emitting phosphor has a Mn % of at least 3 wt %. In another embodiment the Mn % is greater than 3.0 wt %. In another embodiment, the content of Mn in the red-emitting phosphor is from about 1 wt % to about 4 wt %. In another embodiment, the red-emitting phosphor mas a Mn % from about 2 wt % to about 5 wt %.

In one embodiment, the Mn⁴⁺ doped phosphor may be a manganese-doped potassium fluorosilicate, such as K₂SiF₆:Mn⁴⁺ (PFS). PFS has a narrow band emission having multiple peaks with an average full width at half maximum (FWHM) of less than 4 nm. In another embodiment, the red-emitting phosphor may be Na₂SiF₆:Mn⁴⁺ (NFS).

In one embodiment, Mn⁴⁺ doped phosphors may be further treated, such as by annealing, wash treatment, roasting or any combination of these treatments. Post-treatment processes for Mn⁴⁺ doped phosphors are described in U.S. Pat. Nos. 8,906,724, 8,252,613, 9,698,314, US Publication No. 2016/0244663, US Publication No. 2018/0163126, and US Publication No. 2020/0369956. The entire contents of each of which are incorporated herein by reference. In one embodiment, the Mn⁴⁺ doped phosphors may be annealed, treated with multiple wash treatments and roasted.

To improve reliability, the Mn⁴⁺ doped phosphor of Formula I may be at least partially coated with surface coatings to enhance stability of the phosphor particles and resist aggregation by modifying the surface of the particles and increase the zeta potential of the particles. In one embodiment, the surface coatings may be a metal fluoride, silica or organic coating. In one embodiment, the red-emitting phosphors based on complex fluoride materials activated by Mn⁴⁺ phosphors are at least partially coated with a metal fluoride, which increases positive Zeta potential and reduces agglomeration. In one embodiment, the metal fluoride coating includes MgF₂, CaF₂, SrF₂, BaF₂, AgF, ZnF₂, AlF₃ or a combination thereof. In another embodiment, the metal fluoride coating is in an amount from about 0.1 wt % to about 10 wt %. In another embodiment, the metal fluoride coating is present in an amount from about 0.1 wt % to about 5 wt %. In another embodiment, the metal fluoride coating is present from about 0.3 wt % to about 3 wt %. Metal fluoride coated red-emitting phosphors based on complex fluoride materials activated by Mn⁴⁺ are prepared as described in WO 2018/093832, US Publication No. 2018/0163126 and US Publication No. 2020/0369956. The entire contents of each of which are incorporated herein by reference.

A Eu³⁺ doped uranium phosphor has a narrow band emission and is a uranium phosphor in which an energy transfer occurs from the uranium ion to the Europium ion. The energy transfer results in a color shift by the phosphor as measured by a difference in color coordinates ccx and ccy on the CIE chromaticity diagram.

In some embodiments, the Eu³⁺ doped uranium phosphor has formula IIA or IIB:

[Ba_{1-a-b}SrₐCa_{b}]ₓ[Mg,Zn]_{y}(UO₂)_{z}([P,V)]O₄)_{2(x+y+z)/3}:Eu³⁺ (IIA)

[Ba_{1-a-b}SrₐCa_{b}]ₓ[Mg,Zn]_{y}(UO₂)_{z}([P,V)]O₄)_{2(x+y+z)/3}:Eu³⁺ and A (IIB)

wherein 0≤a≤1, 0≤b≤1, 0.75≤x≤1.25, 0.75≤y≤1.25, 0.75≤z≤1.25 and A is Li⁺, Na⁺, K⁺, Rb⁺, Cs⁺, or mixtures thereof. Particular examples include Ba[Mg,Zn]UO₂(PO₄)₂:Eu³⁺, and more particularly, BaMgUO₂(PO₄)₂:Eu³⁺; BaZnUO₂(PO₄)₂:Eu³⁺; BaMgUO₂(PO₄)₂:Eu³⁺ and Li⁺; BaMgUO₂(PO₄)₂:Eu³⁺ and Na⁺; BaMgUO₂(PO₄)₂:Eu³⁺ and K⁺; BaMgUO₂(PO₄)₂:Eu³⁺ and Rb⁺; BaMgUO₂(PO₄)₂:Eu³⁺ and Cs⁺; BaZnUO₂(PO₄)₂:Eu³⁺ and Li⁺, BaZnUO₂(PO₄)₂:Eu³⁺ and Na⁺; BaZnUO₂(PO₄)₂:Eu³⁺ and K⁺; BaZnUO₂(PO₄)₂:Eu³⁺ and Rb⁺; and BaZnUO₂(PO₄)₂:Eu³⁺ and Cs⁺. Uranium phosphors having formula IIA or IIB exhibit an orange, orange/red or red emission.

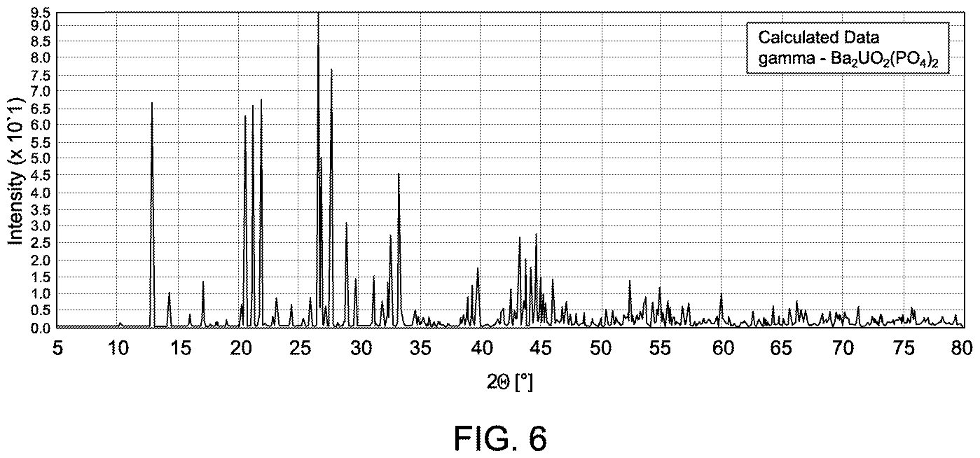

In some embodiments, the Eu³⁺ doped uranium phosphor has formula IIIA or IIIB:

[Ba_{1-a-b}SrₐCa_{b}]ₚ(UO₂)_{q}[P,V]ᵣO_{(2p+2q+5r)/2}:Eu³⁺ (IIIA)

[Ba_{1-a-b}SrₐCa_{b}]ₚ(UO₂)_{q}[P,V]ᵣO_{(2p+2q+5r)/2}:Eu³⁺ and A (IIIB)

wherein 0≤a≤1, 0≤b≤1, 2.5≤p≤3.5, 1.75≤q≤2.25, 3.5≤r≤4.5 and A is Li⁺, Na⁺, K⁺, Rb⁺, Cs⁺, or mixtures thereof. Particular examples include Ba₃(PO₄)₂(UO₂)₂P₂O₇:Eu³⁺; Ba₃(PO₄)₂(UO₂)₂P₂O₇:Eu³⁺ and Li⁺; Ba₃(PO₄)₂(UO₂)₂P₂O₇:Eu³⁺ and Na⁺; Ba₃(PO₄)₂(UO₂)₂P₂O₇:Eu³⁺ and K⁺; Ba₃(PO₄)₂(UO₂)₂P₂O₇:Eu³⁺ and Rb⁺; Ba₃(PO₄)₂(UO₂)₂P₂O₇:Eu³⁺ and Cs⁺Ba₃(PO₄)₂(UO₂)₂V₂O₇:Eu³⁺; Ba₃(PO₄)₂(UO₂)₂V₂O₇:Eu³⁺ and Li⁺; Ba₃(PO₄)₂(UO₂)₂V₂O₇:Eu³⁺ and Na⁺; Ba₃(PO₄)₂(UO₂)₂V₂O₇:Eu³⁺ and K⁺; Ba₃(PO₄)₂(UO₂)₂V₂O₇:Eu³⁺ and Rb⁺; Ba₃(PO₄)₂(UO₂)₂V₂O₇:Eu³⁺ and Cs⁺; γ-Ba₂UO₂(PO₄)₂:Eu³⁺; γ-Ba₂UO₂(PO₄)₂:Eu³⁺ and Li⁺; γ-Ba₂ UO₂(PO₄)₂:Eu³⁺ and Na⁺; gamma γ-Ba₂ UO₂(PO₄)₂:Eu³⁺ and K⁺; γ-Ba₂UO₂(PO₄)₂:Eu³⁺ and Rb⁺; and γ-Ba₂ UO₂(PO₄)₂:Eu³⁺ and Cs⁺. In one embodiment, when the formula is [Ba], p is 3.5, q is 1.75, [P] and r is 3.5, the base compound is Ba₂UO₂(PO₄)₂:Eu³⁺ and A and the compound is in the gamma phase. In another embodiment, when the formula is Ba₂UO₂(PO₄)₂:Eu³⁺ and A, the phosphor is in the gamma phase and is γ-Ba₂ UO₂(PO₄)₂:Eu³⁺ and A. Phosphor gamma phase Baz UO₂(PO₄)₂ described in PCT Publication No. WO 2021/211600, which is incorporated herein by reference. Gamma phase Ba₂UO₂(PO₄)₂ or γ-Ba₂UO₂(PO₄)₂ having an XRD powder pattern as shown in FIG. 6. Uranium phosphors having formula IIIA or IIIB exhibit an orange, orange/red or red emission.

In other embodiments the Eu³⁺ doped uranium phosphor has formula IV:

A₂UO₂[P,V]₂O₇:Eu³⁺ (IV)

where A is Li, Na, K, Rb, Cs, or a combination thereof. Particular examples include A₂UO₂P₂O₇:Eu³⁺ and more particularly, Na₂UO₂P₂O₇:Eu³⁺ and K₂UO₂P₂O₇:Eu³⁺. Uranium phosphors having formula IV exhibit an orange, orange/red or red emission.

In one embodiment, the Eu³⁺ doped uranium phosphor includes a Europium ion, Eu³⁺ in an amount of from about 0.001 to about 10 mole percent. In another embodiment, the Europium ion may be present in an amount of from about 0.01 mole percent to about 10 mole percent. In another embodiment, the Europium ion may be present in an amount from about 0.1 mole percent to about 10 mole percent. In another embodiment, the Europium ion may be present in an amount from about 0.5 to about 5 mole percent. In another embodiment, the Europium ion may be present from about 1 to about 3 mole percent. In another embodiment, the Europium ion may be present from about 0.01 mole percent to about 1 mole percent. In another embodiment, the Europium ion may be present from about 0.05 mole percent to about 1 mole percent. In another embodiment, the Europium ion may be present from about 0.1 mole percent to about 1 mole percent. In another embodiment, the Europium ion may be present from about 0.5 mole percent to about 1 mole percent.

In some embodiments, the Eu³⁺ doped uranium phosphor includes one or more alkali metal ions, such as Li⁺, Na⁺, K⁺, Rb⁺, Cs⁺, or mixtures thereof. The alkali metal ion may be present in an amount from about 0.01 mole percent to about 10 mole percent. In one embodiment, the alkali metal ion may be present in an amount of from about 0.1 to about 10 molar percent. In another embodiment, the alkali metal ion may be present in an amount of from about 0.5 to about 5 mole percent. In another embodiment, the alkali metal ion may be present from about 1 to about 3 mole percent. In another embodiment, the alkali metal ion may be present from about 0.01 mole percent to about 1 mole percent. In another embodiment, the alkali metal ion may be present from about 0.05 mole percent to about 1 mole percent. In another embodiment, the alkali metal ion may be present from about 0.1 mole percent to about 1 mole percent. In another embodiment, the alkali metal ion may be present from about 0.5 mole percent to about 1 mole percent.

In one embodiment, the Eu³⁺ doped uranium phosphor is Na₂UO₂P₂O₇:Eu³⁺. Na₂UO₂P₂O₇:Eu³⁺ has a narrow band red emission with a peak emission at 618 nm. Na₂UO₂P₂O₇:Eu³⁺ can absorb blue light from a blue LED completely and fully convert blue light.

The Eu³⁺ doped uranium phosphors of the present disclosure may be produced by firing a mixture of precursors under an oxidizing atmosphere. Non-limiting examples of suitable precursors include the appropriate metal oxides, hydroxides, alkoxides, carbonates, nitrates, aluminates, silicates, citrates, oxalates, carboxylates, tartarates, stearates, nitrites, peroxides, phosphates, pyrophosphates, alkali salts and combinations thereof. Suitable materials for use as precursors include, but are not limited to, BaCO₃, BaHPO₄, Ba₃(PO₄)₂, Ba₂P₂O₇, Ba₂Zn(PO₄)₂, BaZnP₂O₇, Ba(OH)₂, Ba(C₂O₄), Ba(C₂H₃O₂)₂, Ba₃(C₆H₅O₇)₂, Ba(NO₃)₂, CaCO₃, Cs₂CO₃, HUO₂PO₄—4H₂O, KH₂PO₄, K₂HPO₄, K₂CO₃, Li₂CO₃, Li₂HPO₄, LiH₂PO₄, Mg(C₂O₄), Mg(C₂H₃O₂)₂, Mg(C₆H₆O₇), MgCO₃, MgO, Mg(OH)₂, Mg₃(PO₄)₂, Mg₂P₂O₇, Mg₂Ba(PO₄)₂, MgHPO₄, Mg(NO₃)₂, NaH₂PO₄, Na₂HPO₄, Na₂CO₃, NH₄MgPO₄, (NH₄)₂HPO₄, NH₄VO₃, Rb₂CO₃, SrCO₃, Zn(C₂O₄), Zn(C₂H₃O₂)₂, Zn₃(C₆H₅O₇)₂, ZnCO₃, ZnO, Zn(OH)₂, Zn₃(PO₄)₂, Zn₂P₂O₇, Zn₂Ba(PO₄)₂, ZnHPO₄, Zn(NO₃)₂, NH₄ZnPO₄, UO₂, UO₂(NO₃)₂, (UO₂)₂P₂O₇, (UO₂)₃(PO₄)₂, NH₄ (UO₂)PO₄, UO₂CO₃, UO₂(C₂H₃O₂)₂, UO₂(C₂O₄), H(UO₂)PO₄, UO₂(OH)₂, and ZnUO₂(C₂H₃O₂)₄, and various hydrates. For example, the exemplary phosphor BaZnUO₂(PO₄)₂ may be produced by mixing the appropriate amounts of BaCO₃, ZnO, and UO₂ with the appropriate amount of (NH₄)₂HPO₄ and then firing the mixture under an air atmosphere. The precursors may be in solid form or in solution. Non-limiting examples of solvents include water, ethanol, acetone, and isopropanol, and suitability depends chiefly on solubility of the precursors in the solvent. After firing, the phosphor may be milled to break up any agglomerates that may have formed during the firing procedure.

The mixture of starting materials for producing the Eu³⁺ doped uranium phosphor includes, but is not limited to, Eu₂O₃ or EuPO₄.

The mixture of starting materials for producing the phosphor may also include one or more low melting temperature flux materials, such as boric acid, borate compounds such as lithium tetraborate, alkali phosphates, and combinations thereof. Non-limiting examples include (NH₄)₂HPO₄ (DAP). Li₃PO₄, Na₃PO₄, NaBO₃—H₂O, Li₂B₄O₇, K₄P₂O₇, Na₄P₂O₇, H₃BO₃, and B₂O₃. The flux may lower the firing temperature and/or firing time for the phosphor. If a flux is used, it may be desirable to wash the final phosphor product with a suitable solvent to remove any residual soluble impurities that may have originated from the flux.

The firing of the samples is generally done in air, but since the uranium is in its highest oxidation state (U⁶⁺) it can also be fired in O₂ or other wet or dry oxidizing atmospheres, including at oxygen partial pressures above one atmosphere, at a temperature between about 300° C. and about 1300° C., particularly between about 500° C. and about 1200° C., for a time sufficient to convert the mixture to the phosphor. The firing time required may range from about one to twenty hours, depending on the amount of the mixture being fired, the extent of contact between the solid and the gas of the atmosphere, and the degree of mixing while the mixture is fired or heated. The mixture may rapidly be brought to and held at the final temperature, or the mixture may be heated to the final temperature at a lower rate such as from about 2° C./minute to about 200° C./minute.

The red phosphor material blends a narrow band Mn⁴⁺ doped phosphor of Formula I and a narrow band Eu³⁺ doped uranium phosphor. The red phosphor material may include additional phosphors with orange, red/orange or red emission (from about 585 nm to about 780 nm). The red phosphor material has a red decay rate, which is the weighted average of the decay rate for each of the phosphors in the red phosphor material, based on the total weight of the red phosphor material. In one embodiment, the decay rate of the red phosphor material is the weighted average of a decay rate of the Mn⁴⁺ doped phosphor of formula I and a decay rate of the Eu³⁺ doped uranium phosphors, based on the total weight of the red phosphor material. In another embodiment, when the red phosphor material includes one or more additional phosphors with orange, red/orange or red emissions, the red decay rate is the weighted average of a decay rate of the Mn⁴⁺ doped phosphor of formula I, a decay rate of the Eu³⁺ doped uranium phosphor, and one or more decay rate(s) for the one or more additional phosphors, based on the total weight of the red phosphor material.

In one embodiment, the red phosphor material includes from about 1 weight percent to about 99 weight percent of a Mn⁴⁺ doped phosphor of Formula I and from about 99 weight percent to about 1 weight percent of a Eu³⁺ doped uranium phosphor. In another embodiment, the red phosphor material includes from about 10 weight percent to about 90 weight percent of a Mn⁴⁺ doped phosphor of Formula I and about 90 weight percent to about 10 weight percent of a Eu³⁺ doped uranium phosphor. In another embodiment, the red phosphor material includes from about 20 weight percent to about 80 weight percent of a Mn⁴⁺ doped phosphor of Formula I and from about 80 weight percent to about 20 weight percent of a Eu³⁺ doped uranium phosphor. In another embodiment, the red phosphor material includes from about 30 weight percent to about 70 weight percent of a Mn⁴⁺ doped phosphor of Formula I and from about 70 weight percent to about 30 weight percent of a Eu³⁺ doped uranium phosphor. In another embodiment, the red phosphor material includes from about 40 weight percent to about 60 weight percent of a Mn⁴⁺ doped phosphor of Formula I and from about 60 weight percent to about 40 weight percent of a Eu³⁺ doped uranium phosphor. In another embodiment, the red phosphor material includes from about 45 weight percent to about 55 weight percent of a Mn⁴⁺ doped phosphor of Formula I and from about 55 weight percent to about 45 weight percent of a Eu³⁺ doped uranium phosphor. In another embodiment, the red phosphor material includes about 50 weight percent of a Mn⁴⁺ doped phosphor of Formula I and about 50 weight percent of a Eu³⁺ doped uranium phosphor. In another embodiment, the red phosphor material includes from about 1 weight percent to about 50 weight percent of a Mn⁴⁺ doped phosphor of Formula I and about 50 weight percent to about 1 weight percent of a Eu³⁺ doped uranium phosphor. The percentages by weight are based on the total weight of the red phosphor material.

In one embodiment, the red phosphor material includes from about 1 weight percent to about 99 weight percent of a Mn⁴⁺ doped phosphor of Formula I. In another embodiment, the red phosphor material includes from about 10 weight percent to about 90 weight percent of a Mn⁴⁺ doped phosphor of Formula I. In another embodiment, the red phosphor material includes from about 20 weight percent to about 80 weight percent of a Mn⁴⁺ doped phosphor of Formula I. In another embodiment, the red phosphor material includes from about 30 weight percent to about 70 weight percent of a Mn⁴⁺ doped phosphor of Formula I. In another embodiment, the red phosphor material includes from about 40 weight percent to about 60 weight percent of a Mn⁴⁺ doped phosphor of Formula I. In another embodiment, the red phosphor material includes from about 45 weight percent to about 55 weight percent of a Mn⁴⁺ doped phosphor of Formula I. In another embodiment, the red phosphor material includes about 50 weight percent of a Mn⁴⁺ doped phosphor of Formula I. In another embodiment, the red phosphor material includes from about 1 weight percent to about 50 weight percent of a Mn⁴⁺ doped phosphor of Formula I. In another embodiment, the red phosphor material includes from about 50 weight percent to about 99 weight percent of a Mn⁴⁺ doped phosphor of Formula I. The percentages by weight are based on the total weight of the red phosphor material.

In one embodiment, the red phosphor material includes from about 1 weight percent to about 99 weight percent of a Eu³⁺ doped uranium phosphor. In another embodiment, the red phosphor material includes from about 10 weight percent to about 90 weight percent of a Eu³⁺ doped uranium phosphor. In another embodiment, the red phosphor material includes from about 20 weight percent to about 80 weight percent of a Eu³⁺ doped uranium phosphor. In another embodiment, the red phosphor material includes from about 30 weight percent to about 70 weight percent of a Eu³⁺ doped uranium phosphor. In another embodiment, the red phosphor material includes from about 40 weight percent to about 60 weight percent of a Eu³⁺ doped uranium phosphor. In another embodiment, the red phosphor material includes from about 45 weight percent to about 55 weight percent of a Eu³⁺ doped uranium phosphor. In another embodiment, the red phosphor material includes about 50 weight percent of a Eu³⁺ doped uranium phosphor. In another embodiment, the red phosphor material includes from about 1 weight percent to about 50 weight percent of a Eu³⁺ doped uranium phosphor. In another embodiment, the red phosphor material includes from about 50 weight percent to about 99 weight percent of a Eu³⁺ doped uranium phosphor. The percentages by weight are based on the total weight of the red phosphor material.

In one embodiment, the red phosphor material includes Na₂UO₂P₂O₇:Eu³⁺ and NazSiF₆:Mn⁴⁺ (NFS) In another embodiment, the red phosphor material includes Na₂UO₂P₂O₇:Eu³⁺ and K₂SiF₆:Mn⁴⁺ (PFS).

Mn⁴⁺ doped phosphors of formula I have large color gamuts, while Eu³⁺ doped uranium phosphors have a smaller color gamut and shorter decay rates than the Mn⁴⁺ phosphors of formula I. Blending the phosphors results in a red phosphor material having a shorter red decay time than a Mn⁴⁺ doped phosphor of formula I, while maintaining a large color gamut.

The phosphor composition includes a green phosphor material. The green phosphor material includes at least one green-emitting phosphor. The green-emitting phosphor may include any suitable green-emitting phosphor.

In one embodiment, the green-emitting phosphor may include a narrow-band uranium-based phosphor having formulas V, VI, VII, VIII or IX

[Ba_{1-a-b}SrₐCa_{b}]ₓ[Mg,Zn]_{y}(UO₂)_{z}([P,V]O₄)_{2(x+y+z)/3} (V),

[Ba_{1-a-b}SrₐCa_{b}]ₚ(UO₂)_{q}[P,V]ᵣO_{(2p+2q+5r)/2} (VI),

A₂UO₂ [P,V]₂O₇ (VII),

A₄UO₂([P,V]O₄)₂ (VIII), or

AUO₂([P,V]O₃)₃ (IX)

where 0≤a≤1, 0≤b≤1, 0.75≤x≤1.25, 0.75≤y≤1.25, 0.75≤z≤1.25; 2.5≤p≤3.5, 1.75≤q≤2.25, 3.5≤r≤4.5 and A is Li, Na, K, Rb, Cs, or a combination thereof. These phosphors exhibit a green emission.

Examples of uranium phosphors include Ba₃(PO₄)₂(UO₂)₂P₂O₇, Ba₃(PO₄)₂(UO₂)₂V₂O₇, gamma γ-Ba₂UO₂(PO₄)₂, BaMgUO₂(PO₄)₂, BaZnUO₂(PO₄)₂, Na₂UO₂P₂O₇, K₂UO₂P₂O₇, Rb₂UO₂P₂O₇, Cs₂UO₂P₂O₇, K₄UO₂(PO₄)₂, KUO₂(VO₄)₂, NaUO₂P₃O₉.

The uranium phosphors may be prepared as shown above for the Eu³⁺ doped uranium phosphors without the addition of the Europium starting materials, such as Eu₂O₃ or EuPO₄.

In other embodiments, the green phosphor material includes Beta-SiAlON.

The green phosphor material has a green decay rate, which is the weighted average of the decay rate for each of the phosphors in the green phosphor material, based on the total weight of the green phosphor material.

The phosphor composition includes a red phosphor material and a green phosphor material. In one embodiment, the composition includes from about 1 weight percent to about 99 weight percent of the red phosphor material and from about 99 weight percent to about 1 weight percent of the green phosphor material. In another embodiment, the composition includes from about 10 weight percent to about 90 weight percent of the red phosphor material and about 90 weight percent to about 10 weight percent of the green phosphor material. In another embodiment, the composition includes from about 20 weight percent to about 80 weight percent of the red phosphor material and from about 80 weight percent to about 20 weight percent of the green phosphor material. In another embodiment, the composition includes from about 30 weight percent to about 70 weight percent of the red phosphor material and from about 70 weight percent to about 30 weight percent of the green phosphor material. In another embodiment, the composition includes from about 40 weight percent to about 60 weight percent of the red phosphor material and from about 60 weight percent to about 40 weight percent of the green phosphor material. In another embodiment, the composition includes from about 45 weight percent to about 55 weight percent of the red phosphor material and from about 55 weight percent to about 45 weight percent of the green phosphor material. In another embodiment, the composition includes about 50 weight percent of the red phosphor material and about 50 weight percent of the green phosphor material. In another embodiment, the composition includes from about 1 weight percent to about 50 weight percent of the red phosphor material and about 50 weight percent to about 1 weight percent of the green phosphor material. The percentages by weight are based on the total weight of the composition.

In one embodiment, the phosphor composition includes from about 1 weight percent to about 99 weight percent of the red phosphor material. In another embodiment, the composition includes from about 10 weight percent to about 90 weight percent of the red phosphor material. In another embodiment, the composition includes from about 20 weight percent to about 80 weight percent of the red phosphor material. In another embodiment, the composition includes from about 30 weight percent to about 70 weight percent of the red phosphor material. In another embodiment, the composition includes from about 40 weight percent to about 60 weight percent of the red phosphor material. In another embodiment, the composition includes from about 45 weight percent to about 55 weight percent of the red phosphor material. In another embodiment, the composition includes about 50 weight percent of the red phosphor material. In another embodiment, the composition includes from about 1 weight percent to about 50 weight percent of the red phosphor material. In another embodiment, the composition includes from about 50 weight percent to about 99 weight percent of the red phosphor material. The percentages by weight are based on the total weight of the phosphor composition.

In one embodiment, the phosphor composition includes from about 1 weight percent to about 99 weight percent of the green phosphor material. In another embodiment, the composition includes from about 10 weight percent to about 90 weight percent of the green phosphor material. In another embodiment, the composition includes from about 20 weight percent to about 80 weight percent of the green phosphor material. In another embodiment, the composition includes from about 30 weight percent to about 70 weight percent of the green phosphor material. In another embodiment, the composition includes from about 40 weight percent to about 60 weight percent of the green phosphor material. In another embodiment, the composition includes from about 45 weight percent to about 55 weight percent of the green phosphor material. In another embodiment, the composition includes about 50 weight percent of the green phosphor material. In another embodiment, the composition includes from about 1 weight percent to about 50 weight percent of the green phosphor material. In another embodiment, the composition includes from about 50 weight percent to about 99 weight percent of the green phosphor material. The percentages by weight are based on the total weight of the phosphor composition.

Minimizing the decay rate mismatch between the red phosphor material and the green phosphor material in a phosphor composition to less than 7 milliseconds results in a phosphor composition with a reduced color shift and faster response times in displays. In another embodiment, a difference between the red decay rate and the green decay rate is less than 6 milliseconds. In another embodiment, a difference between the red decay rate and the green decay rate is less than 5 milliseconds. In another embodiment, a difference between the red decay rate and the green decay rate is less than 4 milliseconds. In another embodiment, a difference between the red decay rate and the green decay rate is less than 3 milliseconds. In another embodiment, a difference between the red decay rate and the green decay rate is from about 0 ms to about 7 ms. In another embodiment, a difference between the red decay rate and the green decay rate is from about 0 ms to about 6 ms. In another embodiment, a difference between the red decay rate and the green decay rate is from about 0 ms to about 5 ms. In another embodiment, a difference between the red decay rate and the green decay rate is from about 0 ms to about 4 ms. In another embodiment, a difference between the red decay rate and the green decay rate is from about 0 ms to about 3 ms.

The phosphors may be in particulate form. In some embodiments, the median particle size of the phosphors may range from about 1 to about 50 microns. In another embodiment, the median particle size may range from about 15 to about 35 microns. In another embodiment, the median particle size may be about 30 microns or less.

In another embodiment, the phosphors are in particulate form including a monodisperse population of particles having a population of particles including a D50 particle size diameter in the range from about 0.1 μm to about 15 μm. In another embodiment, the particle size diameter is in the range from about 0.1 μm to about 10 μm. In another embodiment, the particle size distribution that is, D50 of less than 15 μm, particularly, D50 of less than 10 μm, particularly D50 of less than 5 μm, or D50 of less than 3 μm, or D50 of less than 2 μm, or D50 of less than 1 μm. In another embodiment, the particle size distribution D50 may be in a range from about 0.1 μm to about 5 μm. In another embodiment, the D50 particle size is in a range from about 0.1 μm to about 3 μm. In another embodiment, the D50 particle size is in a range from about 0.1 μm to about 1 μm. In another embodiment, the D50 particle size is in a range from about 1 μm to about 5 μm. D50 (also expressed as D50) is defined as the median particle size for a volume distribution. D90 or D90 is the particle size for a volume distribution that is greater than the particle size of 90% of the particles of the distribution. D10 or D₁₀ is the particle size for a volume distribution that is greater than the particle size of 10% of the particles of the distribution. Particle size of the phosphors may be conveniently measured by laser diffraction or optical microscopy methods, and commercially available software can generate the particle size distribution and span. Span is a measure of the width of the particle size distribution curve for a particulate material or powder, and is defined according to the equation:

$$Span = \frac{( {D}_{90} - {D}_{10} )}{{D}_{50}}$$

wherein D90, D10 and D50 are defined above. For phosphor particles, span of the particle size distribution is not necessarily limited and may be ≤1.0 in some embodiments.

The phosphor composition may include, one or more other luminescent materials. Additional luminescent materials, such as blue, yellow, red, orange, or other color phosphors may be used in the phosphor composition to customize the white color of the resulting light and produce specific spectral power distributions.

Suitable phosphors for use in the phosphor composition, include, but are not limited to: ((Sr_{1-z}[Ca,Ba,Mg,Zn]_{z})_{1-(x+w)}[Li,Na,K,Rb]_{w}Ceₓ)₃(Al_{1-y}Si_{y})O_{4+y+3(x-w)}F_{1-y-3(x-w)}, 0<x≤0.10, 0≤y≤0.5, 0≤z≤0.5, 0≤w≤x; [Ca,Ce]₃Sc₂Si₃O₁₂ (CaSiG); [Sr,Ca,Ba]₃Al₁₋ₓSiₓO₄₊ₓF₁₋ₓ:Ce³⁺ (SASOF)); [Ba,Sr,Ca]₅(PO₄)₃[Cl,F,Br,OH]:Eu²⁺, Mn²⁺; [Ba,Sr,Ca]BPO₅:Eu²⁺, Mn²⁺; [Sr,Ca]₁₀(PO₄)₆*vB₂O₃:Eu²⁺ (wherein 0<v≤1); Sr₂Si₃O₈*2SrCl₂:Eu²⁺; [Ca,Sr,Ba]₃MgSi₂O₈:Eu²⁺,Mn²⁺; BaAl₈O₁₃:Eu²⁺; 2SrO*0.84P₂O₅*0.16B₂O₃:Eu²⁺; [Ba,Sr,Ca]MgAl₁₀O₁₇:Eu²⁺, Mn²⁺; [Ba,Sr,Ca] Al₂O₄:Eu²⁺; [Y,Gd,Lu,Sc,La]BO₃:Ce³⁺,Tb³⁺; ZnS:Cu⁺,Cl⁻; ZnS:Cu⁺, Al³⁺; ZnS:Ag⁺, Cl⁻; ZnS:Ag⁺,Al³⁺; [Ba,Sr,Ca]₂Si₁₋ₙO₄₋₂ₙ:Eu²⁺ (wherein 0≤n≤0.2); [Ba,Sr,Ca]₂[Mg,Zn]Si₂O₇:Eu²⁺; [Sr,Ca,Ba][Al,Ga,In]₂S₄:Eu²⁺; [Y,Gd,Tb,La,Sm,Pr,Lu]₃[Al,Ga]₅₋ₐO_{12-3/2a}:Ce³⁺ (wherein 0≤a≤0.5); [Ca,Sr]₈[Mg,Zn] (SiO₄)₄Cl₂:Eu²⁺,Mn²⁺; Na₂Gd₂B₂O₇:Ce³⁺,Tb³⁺; [Sr,Ca,Ba,Mg,Zn]₂P₂O₇:Eu²⁺, Mn²⁺; [Gd,Y,Lu,La]₂O₃:Eu³⁺, Bi³⁺; [Gd,Y,Lu,La]₂O₂S:Eu³⁺,Bi³⁺; [Gd,Y,Lu,La]VO₄:Eu³⁺,Bi³⁺; [Ca,Sr,Mg]S:Eu²⁺, Ce³⁺; SrY₂S₄:Eu²⁺; CaLa₂S₄:Ce³⁺; [Ba,Sr,Ca]MgP₂O₇:Eu²⁺, Mn²⁺; [Y,Lu]₂WO₆:Eu³⁺, Mo⁶⁺; [Ba,Sr,Ca]_{b}Si_{g}Nm:Eu²⁺ (wherein 2b+4g=3m); Ca₃(SiO₄)Cl₂:Eu²⁺; [Lu,Sc,Y,Tb]₂₋ᵤ₋ᵥCeᵥCa₁₊ᵤLi_{w}Mg_{2-w}P_{w}[Si,Ge]_{3-w}O_{12-u/2} (where 0.5≤u≤1, 0<v≤0.1, and 0≤w≤0.2); [Y,Lu,Gd]₂₋ₘ[Y,Lu,Gd]CaₘSi₄N₆₊ₘC₁₋ₘ:Ce³⁺, (wherein 0≤m≤0.5); [Lu,Ca,Li,Mg,Y], alpha-SiAlON doped with Eu²⁺ and/or Ce³⁺; Sr(LiAl₃N₄):Eu²⁺, [Ca,Sr,Ba] SiO₂N₂:Eu²⁺, Ce³⁺; beta-SiAlON:Eu²⁺; 3.5MgO*0.5MgF₂*GeO₂:Mn⁴⁺; Ca_{1-c-f}Ce_{c}Eu_{f}Al_{1+c}Si_{1-c}N₃, (where 0≤c≤0.2, 0≤f≤0.2); Ca₁₋ₕ₋ᵣCeₙEuᵣAl₁₋ₕ(Mg,Zn)ₕSiN₃, (where 0≤h≤0.2, 0≤r≤0.2); Ca₁₋₂ₛ₋ₜCe₅[Li,Na]ₛEuₜAlSiN₃, (where 0≤s≤0.2, 0≤t≤0.2, s+t>0); [Sr,Ca]AlSiN₃; and Eu²⁺, Ce³⁺, Li₂CaSiO₄:Eu²⁺.

In particular embodiments, additional phosphors include: [Y,Gd,Lu,Tb]₃[Al,Ga]₅O₁₂:Ce³⁺, β-SiAlON:Eu²⁺, [Sr,Ca,Ba][Ga, Al]₂S₄:Eu²⁺, [Li,Ca]α-SiAlON:Eu²⁺, [Ba,Sr,Ca]₂Si₅N₈:Eu²⁺, [Ca,Sr]AlSiN₃:Eu²⁺, [Ba,Sr,Ca] LiAl₃N₄:Eu²⁺, [Sr,Ca,Mg]S:Eu²⁺, and [Ba,Sr,Ca]₂Si₂O₄:Eu²⁺.

Other additional luminescent materials suitable for use in the phosphor composition may include electroluminescent polymers such as polyfluorenes, preferably poly(9,9-dioctyl fluorene) and copolymers thereof, such as poly(9,9′-dioctylfluorene-co-bis-N,N′-(4-butylphenyl)diphenylamine) (F8-TFB); poly(vinylcarbazole) and polyphenylenevinylene and their derivatives. In addition, the light emitting layer may include a blue, yellow, orange, green or red phosphorescent dye or metal complex, a quantum dot material, or a combination thereof. Materials suitable for use as the phosphorescent dye include, but are not limited to, tris(1-phenylisoquinoline) iridium (III) (red dye), tris(2-phenylpyridine) iridium (green dye) and iridium (III) bis(2-(4,6-difluorephenyl)pyridinato-N,C2) (blue dye). Commercially available fluorescent and phosphorescent metal complexes from ADS (American Dyes Source, Inc.) may also be used. ADS green dyes include ADS060GE, ADS061GE, ADS063GE, and ADS066GE, ADS078GE, and ADS090GE. ADS blue dyes include ADS064BE, ADS065BE, and ADS070BE. ADS red dyes include ADS067RE, ADS068RE, ADS069RE, ADS075RE, ADS076RE, ADS067RE, and ADS077RE.

Exemplary QD materials include, but are not limited to, group II-IV compound semiconductors such as CdS, CdSe, CdS/ZnS, CdSe/ZnS or CdSe/CdS/ZnS, group II-VI, such as CdTe, ZnSe, ZnTe, ZnS, HgTe, HgS, HgSe, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, CdZnSeS, CdZnSeTe, CdZnSTe, CdHgSeS, CdHgSeTe, CdHgSTe, HgZnSeS, HgZnSeTe, HgZnSTe, group III-V or group IV-VI compound semiconductors such as GaN, GaP, GaNP, GaNAs, GaPAs, GaAs, GaAINP, GaAINAs, GaAlPAs, GaInNP, GaInNAs, GalnPAs, AlN, AlNP, AlNAs, AIP, AIPAS, AlAs, InN, InNP, InP, InNAs, InPAs, InAS, InAINP, InAINAs, InAlPAs, PbS/ZnS or PbSe/ZnS, group IV, such as Si, Ge, SiC, and SiGe, chalcopyrite-type compounds, including, but not limited to, CulnS₂, CuInSe₂, CuGaS₂, CuGaSe₂, AgInS₂, AgInSe₂, AgGaS₂, AgGaSe₂ or perovskite QDs having a formula of ABX₃ where A is cesium, methylammonium or formamidinium, B is lead or tin and C is chloride, bromide or iodide.

In one embodiment, the perovskite quantum dot may be CsPbX3, where X is Cl, Br, I or a combination thereof. The mean size of the QD materials may range from about 2 nm to about 20 nm. The surface of QD particles may be further modified with ligands such as amine ligands, phosphine ligands, phosphatide and polyvinylpyridine. In one aspect, the red phosphor may be a quantum dot material.

All of the semiconductor quantum dots may also have appropriate shells or coatings for passivation and/or environmental protection. The QD materials may be a core/shell QD, including a core, at least one shell coated on the core, and an outer coating including one or more ligands, preferably organic polymeric ligands. Exemplary materials for preparing core-shell QDs include, but are not limited to, Si, Ge, Sn, Se, Te, B, C (including diamond), P, Co, Au, BN, BP, BAS, AlN, AIP, AlAs, AlSb, GaN, GaP, GaAs, GaSb, InN, InP, InAs, InSb, AlN, AIP, AlAs, AlSb, GaN, GaP, GaAs, GaSb, ZnO, ZnS, ZnSe, ZnTe, CdS, CdSe, CdSeZn, CdTe, HgS, HgSe, HgTe, BeS, BeSe, BeTe, MgS, MgSe, MnS, MnSe, GeS, GeSe, GeTe, SnS, SnSe, SnTe, PbO, PbS, PbSe, PbTe, CuF, CuCl, CuBr, CuI, Si₃N₄, Ge₃N₄, Al₂O₃, [Al, Ga, In]₂ [S, Se, Te]₃, and appropriate combinations of two or more such materials. Exemplary core-shell luminescent nanocrystals include, but are not limited to, CdSe/ZnS, CdSe/CdS, CdSe/CdS/ZnS, CdSeZn/CdS/ZnS, CdSeZn/ZnS, InP/ZnS, PbSe/PbS, PbSe/PbS, CdTe/CdS and CdTe/ZnS.

In one embodiment, the phosphor composition may include scattering particles. In one embodiment, the scattering particles have a particle size of at least 1 μm. In another embodiment, the scattering particles have a particle size from about 1 μm to about 10 μm. In another embodiment, the scattering particles may include titanium dioxide, aluminum oxide (Al₂O₃), zirconium oxide, indium tin oxide, cerium oxide, tantalum oxide, zinc oxide, magnesium fluoride (MgF₂), calcium fluoride (CaF₂), strontium fluoride (SrF₂), barium fluoride (BaF₂), silver fluoride (AgF), aluminum fluoride (AlF₃) or combinations thereof.

The ratio of each of the individual phosphors and other luminescent materials in the phosphor composition may vary depending on the characteristics of the desired light output. The relative proportions of the individual phosphors and other luminescent materials in the various phosphor compositions may be adjusted such that when their emissions are blended and employed in a device, for example a lighting apparatus, there is produced visible light of predetermined x and y values on the CIE chromaticity diagram.

The phosphor composition may be in the form of an ink or slurry composition, which can be applied to a substrate, such as an LED light source or formed into a film. The ink composition may be blended with a binder or a solvent.

Examples of binders include, but are not limited to silicone polymers, polysiloxanes, ethyl cellulose, polystyrene, polyacrylate, polymethyl acrylate (PMA), polymethyl methacrylate (PMMA), polycarbonate, polyurethane, polyetherether ketone, polysulfone, polyphenylene sulfide, polyvinylpyrrolidone (PVP), polyethyleneimine (PEI), poly(1-naphthyl methacrylate), poly(vinyl phenyl sulfide) (PVPS), polyvinyl alcohol (PVA), polyvinyl butyral (PVB), poly(N-vinylphthalimide), polyvinylidene fluoride (PDVF), poly(vinylidene fluoride-co-hexafluoropropylene) (PVDF-HFP), silicone materials and UV-curable materials, such as epoxy resins, acrylic resins, acrylate resins and urethane-based materials.

Examples of solvents include, but are not limited to, water, ethanol, acetone and isopropanol.

In another aspect, a device includes an LED light source optically coupled and/or radiationally connected to a phosphor composition, wherein the phosphor composition includes a red phosphor material having a red decay rate and a green phosphor material having a green decay rate, wherein the red phosphor material includes a Mn⁴⁺ doped phosphor of formula I and a Eu³⁺ doped uranium phosphor, and wherein a difference between the red decay rate and the green decay rate is no more than 7 ms,

AₓMF_{y}:Mn⁴⁺ (I),

wherein A is Li, Na, K, Rb, Cs, or a combination thereof; M is Si, Ge, Sn, Ti, Zr, Al, Ga, In, Sc, Hf, Y, La, Nb, Ta, Bi, Gd, or a combination thereof; x is an absolute value of a charge of the MF_{y} ion; and y is 5, 6 or 7.

In one embodiment, a lighting apparatus includes the device. In another embodiment, a backlight apparatus includes the device. In another embodiment, a display includes the device. In another embodiment, the device is a self-emissive display and does not contain a liquid crystal display (LCD). In one embodiment, the display is a micro-LED display, such as a phosphor-converted microLED display.

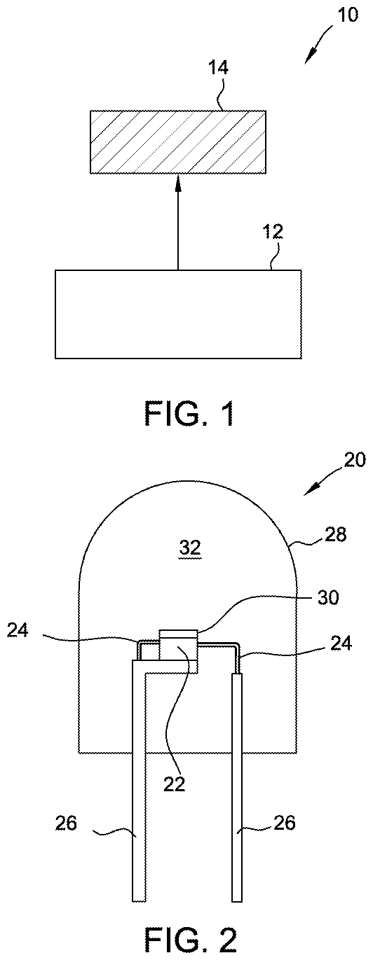

Devices according to the present disclosure include an LED light source radiationally connected and/or optically coupled to the phosphor composition. FIG. 1 shows a device 10, according to one embodiment of the present disclosure. The device 10 includes an LED light source 12 and the phosphor composition 14. The LED light source 12 may be a UV or blue emitting LED. In some embodiments, the LED light source 12 produces blue light in a wavelength range from about 380 nm to about 460 nm. In the device 10, the phosphor composition 14 is radiationally coupled and/or optically coupled to the LED light source 12. Radiationally connected or coupled or optically coupled means that radiation from the LED light source 12 is able to excite the phosphor composition 14, and the phosphor composition 14 is able to emit light in response to the excitation by the radiation. The phosphor composition 14 may be disposed on a part or portion of the LED light source 12 or located remotely at a distance from the LED light source 12. In some embodiments, the device may be a backlight unit for display applications. In other embodiments, the LED light source 12 is a mico-LED and the device is for a self-emissive display.

The general discussion of the example LED light source discussed herein is directed toward an inorganic LED based light source. The most popular white LEDs are based on blue or UV emitting GaInN chips. In addition, to inorganic LED light sources, the term LED light source is meant to encompass all LED light sources such as semiconductor laser diodes (LD), organic light emitting diodes (OLED) or a hybrid of LED and LD. The LED light source may be a miniLED or microLED, which can be used in self-emissive displays. Further, it should be understood that the LED light source may be replaced, supplemented or augmented by another radiation source unless otherwise noted and that any reference to semiconductor, semiconductor LED, or LED chip is merely representative of any appropriate radiation source, including, but not limited to, LDs and OLEDs.

The phosphor composition 14 may be present in any form such as powder, glass, or composite e.g., phosphor-polymer composite or phosphor-glass composite. Further, the phosphor composition 14 may be used as a layer, sheet, film, strip, dispersed particulates, or a combination thereof. In some embodiments, the phosphor composition 14 includes the uranium-based phosphor material in glass form. In some of these embodiments, the device 10 may include the phosphor composition 14 in form of a phosphor wheel (not shown). The phosphor wheel may include the phosphor composition embedded in a glass. A phosphor wheel and related devices are described in WO 2017/196779.

The phosphor composition is optically coupled or radiationally connected to an LED light source. In one embodiment, a white light blend may be obtained by blending the red phosphor material and the green phosphor material with an LED light source, such as a blue or UV LED.

FIG. 2 illustrates a lighting apparatus or lamp 20, in accordance with some embodiments. In one embodiment, the lighting apparatus 20 may be a backlight apparatus. The lighting apparatus 20 includes an LED chip 22 and leads 24 electrically attached to the LED chip 22. The leads 24 may comprise thin wires supported by a thicker lead frame(s) 26 or the leads 24 may comprise self-supported electrodes and the lead frame may be omitted. The leads 24 provide current to LED chip 22 and thus cause it to emit radiation.

A layer 30 of the phosphor composition is disposed on a surface of the LED chip 22. The phosphor layer 30 may be disposed by any appropriate method, for example, using a slurry or ink composition prepared by mixing the phosphor composition and a binder material or solvent (as discussed above). In one such method, a silicone slurry in which the phosphor composition particles are randomly suspended or uniformly dispersed is placed around the LED chip 22. This method is merely exemplary of possible positions of the phosphor layer 30 and LED chip 22. The phosphor layer 30 may be coated over or directly on the light emitting surface of the LED chip 22 by coating and drying the slurry over the LED chip 22. The light emitted by the LED chip 22 mixes with the light emitted by the phosphor composition to produce desired emission.

With continued reference to FIG. 2, the LED chip 22 may be encapsulated within an envelope 28. The envelope 28 may be formed of, for example glass or plastic. The LED chip 22 may be enclosed by an encapsulant material 32. The encapsulant material 32 may be a low temperature glass, or a polymer or resin known in the art, for example, an epoxy, silicone, epoxy-silicone, acrylate or a combination thereof. In an alternative embodiment, the lighting apparatus 20 may only include the encapsulant material 32 without the envelope 28. Both the envelope 28 and the encapsulant material 32 should be transparent to allow light to be transmitted through those elements.

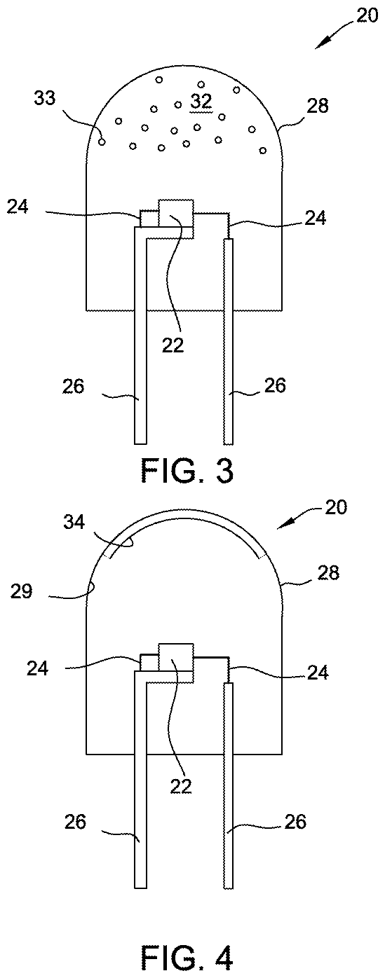

In some embodiments as illustrated in FIG. 3, the phosphor composition 33 is interspersed within the encapsulant material 32, instead of being formed directly on the LED chip 22, as shown in FIG. 2. The phosphor composition 33 may be interspersed within a portion of the encapsulant material 32 or throughout the entire volume of the encapsulant material 32. Blue light or UV light emitted by the LED chip 22 mixes with the light emitted by phosphor composition 33, and the mixed light transmits out from the lighting apparatus 20.

In yet another embodiment, a layer 34 of the phosphor composition is coated onto a surface of the envelope 28, instead of being formed over the LED chip 22, as illustrated in FIG. 4. As shown, the phosphor layer 34 is coated on an inside surface 29 of the envelope 28, although the phosphor layer 34 may be coated on an outside surface of the envelope 28, if desired. The phosphor layer 34 may be coated on the entire surface of the envelope 28 or only a top portion of the inside surface 29 of the envelope 28. The UV/blue light emitted by the LED chip 22 mixes with the light emitted by the phosphor layer 34, and the mixed light transmits out. Of course, the phosphor composition may be located in any two or all three locations (as shown in FIGS. 2-4) or in any other suitable location, such as separately from the envelope 28, remote or integrated into the LED chip 22. In one embodiment, the phosphor layer 34 may be a film and located remotely from the LED chip 22. In another embodiment, the phosphor layer 34 may be a film and disposed on the LED chip 22. In some embodiments, the phosphor layer 34 may be applied to the LED chip 22 as an ink composition. In some embodiments, the phosphor layer 34 may be applied to the LED chip 22 as an ink composition and dried to form a film on the LED chip 22. In some embodiments, the phosphor composition may be a single layer or multi-layered. In some embodiments, the film is a multi-layered structure where each layer of the multi-layered structure includes at least one phosphor or quantum dot material. In another embodiment, a device structure includes a layer of a phosphor composition on an LED chip and a remote layer including a quantum dot material. In another embodiment, a device structure includes a layer of a phosphor composition on an LED chip and a remote layer including a quantum dot material and phosphor material. In another embodiment, a device structure includes a layer of a phosphor composition on an LED chip and a film including quantum dot material located remotely from the LED chip. In another embodiment, a device structure includes a layer of a phosphor composition on an LED chip and a film including quantum dot material and phosphor material located remotely from the LED chip.

In any of the above structures, the lighting apparatus 20 (FIGS. 2-4) may also include a plurality of scattering particles (not shown), which are embedded in the encapsulant material 32. The scattering particles may comprise, for example, alumina, silica, zirconia, or titania. The scattering particles effectively scatter the directional light emitted from the LED chip 22, preferably with a negligible amount of absorption.

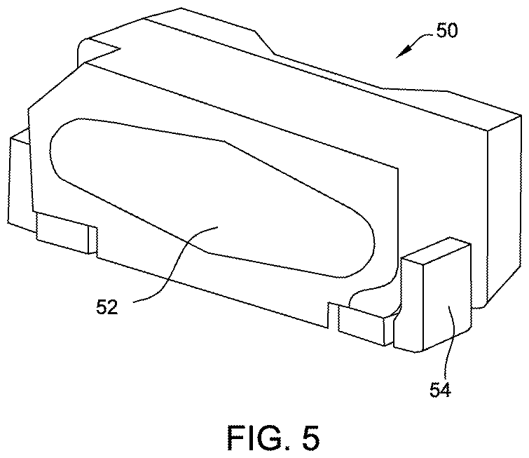

In one embodiment, the lighting apparatus 20 shown in FIG. 3 or FIG. 4 may be a backlight apparatus. In another embodiment, the backlight apparatus comprises a backlight unit 10. Some embodiments include a surface mounted device (SMD) type light emitting diode 50, e.g. as illustrated in FIG. 5, for backlight applications. This SMD is a “side-emitting type” and has a light-emitting window 52 on a protruding portion of a light guiding member 54. An SMD package may comprise an LED chip as defined above, and a phosphor composition including the green-emitting phosphor as described herein. In another embodiment, the device may be a direct lit display.

By use of the phosphor compositions described herein, devices can be provided producing white light for display applications, for example, LCD backlight units, having high color gamut and high luminosity. Alternately, devices can be provided producing white light for general illumination having high luminosity and high CRI values for a wide range of color temperatures of interest (2000 K to 10,000 K).

Devices of the present disclosure include lighting and display apparatuses for general illumination and display applications. Examples of display apparatuses include liquid crystal display (LCD) backlight units, televisions, computer monitors, vehicular displays, laptops, computer notebooks, mobile phones, smartphones, tablet computers and other handheld devices. Where the display is a backlight unit, the phosphor composition may be incorporated in a film, sheet or strip that is radiationally coupled and/or optically coupled to the LED light source, as described in US Patent Application Publication No. 2017/0254943. Examples of other devices include chromatic lamps, plasma screens, xenon excitation lamps, UV excitation marking systems, automotive headlamps, home and theatre projectors, laser pumped devices, and point sensors. In one embodiment, the device may be a fast response display that does not include an LCD. The fast response display may be a self-emissive display including phosphor converted (PC) micro-LEDs. The list of these applications is meant to be merely exemplary and not exhaustive.

In some embodiments, films including the phosphor composition may be disposed on small-size LEDs, such as micro-LEDs or mini-LEDs. In other embodiments, the film includes phosphor particle sizes from about 0.1 to about 15 microns. In other embodiments, of no more than 5 microns. In another embodiment, the film includes phosphor particles sizes of from about 0.1 micron to about 5 microns. In another embodiment, the film includes particle sizes of from about 0.5 micron to about 5 microns. In another embodiment, the film includes particle sizes from about 0.1 micron to about 1 micron. In another embodiment, the film includes particle sizes from about 0.5 micron to about 1 micron. In another embodiment, the film includes particle sizes from about 1 micron to about 3 microns.

Although specific features of various embodiments of the disclosure may be shown in some drawings and not in others, this is for convenience only. In accordance with the principles of the disclosure, any feature of a drawing may be referenced and/or claimed in combination with any feature of any other drawing.

### EXAMPLES

### Example 1

### Preparation of Eu³⁺ doped uranium phosphor Na₂UO₂P₂O₇ doped with 1% molar amount of Eu³⁺ (Sample DU-Red)

Na₂CO₃, HUO₂PO₄-4H₂O, NaH₂PO₄ and Eu₂O₃ were weighted out in a mol ratio of 0.495:1:1:0.005 and then put in a Nalgene bottle with zirconia media and ball milled for two hours. After the mixture was thoroughly blended the powder was transferred into an alumina crucible and fired at 500° C. for 5 hours, the mixture was then sieved through a 40-mesh screen and blended again in the same Nalgene bottle for two additional hours. The powder was put back into the alumina crucible and fired at 900° C. for 5 hours. After the final firing the phosphor powder was obtained. The ccx and ccy values, decay time and refresh rate for Na₂UO₂P₂O₇:Eu³⁺ (DU-Red) are shown in Tables 1 and 2.

### Preparation of BaZnUO₂(PO₄)₂(Sample Green A)

BaHPO₄, HUO₂PO₄—4H₂O, ZnO and DAP were weighed out in a mol ratio of 1:1:1:0.05 and then put in a Nalgene bottle with zirconia media and ball milled for two hours. After the mixture was thoroughly blended the powder was transferred into an alumina crucible and fired at 1050° C. for 5 hours under flowing wet air. After firing, a yellow body-colored powder was obtained. The ccx and ccy values, decay time and refresh rate for BaZnUO₂(PO₄)₂(Green A) are shown in Tables 1 and 2.

### Preparation of gamma-Ba₂UO₂(PO₄)₂(Sample Green B)

For preparing gamma-Ba₂UO₂(PO₄)₂, BaHPO₄, UO₂, and DAP were weighed out in a mol ratio of 2:1:0.05 and then put in a Nalgene bottle with zirconia media and ball milled for two hours. After the mixture was thoroughly blended the powder was transferred into an alumina crucible and fired at 1100° C. for 5 hours in air. After firing a yellow body colored powder was obtained. The cox and ccy values, decay time and refresh rate for gamma-Ba₂UO₂(PO₄)₂(Green B) are shown in Tables 1 and 2. The XRD powder pattern for gamma-Ba₂UO₂(PO₄)₂ is shown in FIG. 6.

TABLE 1

| Sample or | ccx | ccy |
|---|---|---|
| Compound | (Edinburgh) | (Edinburgh) |
| DU-Red | 0.6568 | 0.3429 |
| NSF | 0.6863 | 0.3136 |
| Green A | 0.2187 | 0.6698 |
| Green B | 0.2785 | 0.6731 |
| LED | 0.1529 | 0.0255 |
| | (from calculator) | (from calculator) |
| PFS | 0.6938 | 0.3060 |
| | (from calculator) | (from calculator) |
| Beta-SiAlON | 0.3460 | 0.6307 |
| | (from calculator) | (from calculator) |

TABLE 2

| | Decay | | Refresh | Refresh | Refresh |
|---|---|---|---|---|---|
| Sample | (ms) | Hz | Rate (s) | Rate (ms) | Rate (μs) |
| DU-Red | 1.8 | 120 | 0.008333333 | 8.33333333 | 8333.333 |
| NSF | 6 | 240 | 0.004166667 | 4.166666667 | 4166.667 |
| Green A | 0.52 | 60 | 0.016666667 | 16.66666667 | 16666.67 |
| Green B | 0.09 | | | | |

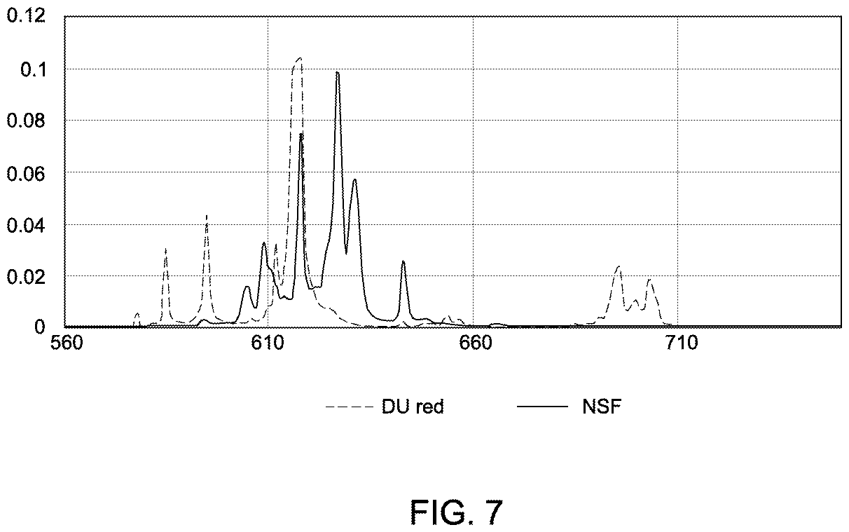

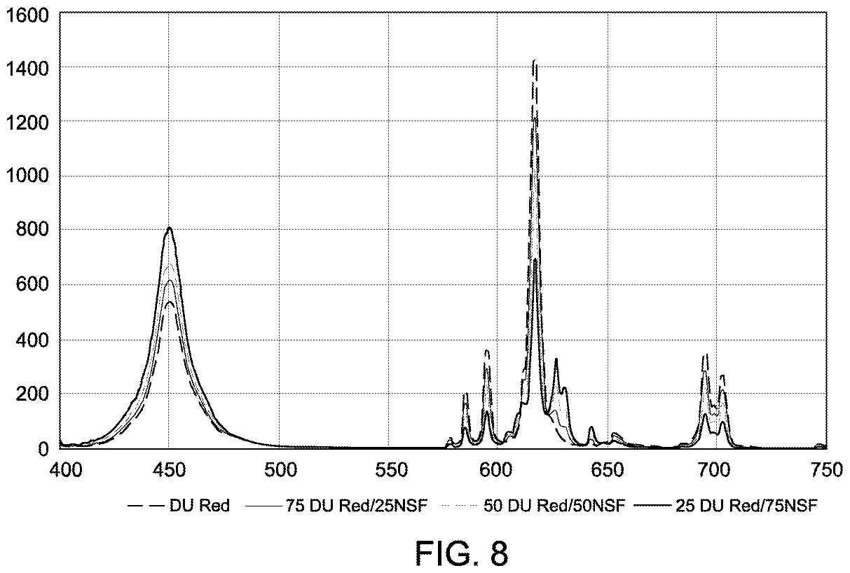

The red phosphor material was prepared by blending the DU-Red sample and the NSF sample in different amounts as shown in Table 3. Quantum efficiency measurements of the red phosphor material were performed on cured silicone tape. Phosphor particles were dispersed in a 2-part thermally curable polydimethylsiloxane elastomer (such as is sold as Sylgard® 184 from Dow Corning) by mixing. The dispersed phosphor particles were prepared at a concentration of 0.17 g of phosphor to 1.8 g of silicone. The mixture was applied to a silicone tape and cured. The quantum efficiencies (QE) of the phosphor particles were measured in these films. The LED was a blue LED with a ccx of 0.1529 and ccy of 0.0205. The QE measurements were reported in relation to the QE of potassium fluoride sulfide phosphors (PFS). The Bleedthrough value is the amount of blue coming through the tape. Data for the red phosphor material is in Table 3 and the emission spectrum for the DU-Red sample and the NFS sample is shown in FIG. 7 and the emission spectrum showing the combination of the DU-Red and NFS samples is in FIG. 8.

TABLE 3

| | | | | | | | | | | Peak | Peak |
|---|---|---|---|---|---|---|---|---|---|---|---|
| DU- | NSF | DU- | | | | | | ccx | ccy | Ratio | ratio |
| Red | Wt. | Red | NSF | | Bleed- | | | with | with | for | for |
| Wt. % | % | Vol. % | Vol. % | QE | through | ccx | ccy | LED | LED | 618 | 627 |
| 100 | 0 | 100 | 0 | 0.948 | 0.405 | 0.6582 | 0.3415 | 0.3461 | 0.1513 | 100 | 0 |
| 75 | 25 | 65.5 | 34.5 | 0.950 | 0.458 | 0.6606 | 0.3391 | 0.3208 | 0.1331 | 89.5 | 10.5 |
| 50 | 50 | 38.8 | 61.2 | 0.950 | 0.501 | 0.6641 | 0.3356 | 0.3027 | 0.1192 | 82 | 18 |
| 25 | 75 | 17.4 | 82.6 | 0.968 | 0.593 | 0.6704 | 0.3294 | 0.2670 | 0.0938 | 68 | 32 |

The decay times for the red phosphor material for the amounts shown in Table 3 and FIG. 8 are shown in Table 4. The red decay rates for the red phosphor material are reduced in comparison with NSF alone. The red phosphor material maintains a good quantum efficiency and large color gamut.

TABLE 4

| | | DU-Red | NSF | Red |
|---|---|---|---|---|
| | | Decay | Decay | Decay |
| DU-Red | NSF | Rate | Rate | Rate |
| Wt. % | Wt. % | (ms) | (ms) | (ms) |
| 100 | 0 | 1.8 | | 1.8 |
| 75 | 25 | 1.8 | 6 | 2.85 |
| 50 | 50 | 1.8 | 6 | 3.9 |
| 25 | 75 | 1.8 | 6 | 4.95 |

TABLE 5

| | | | Mismatch or | Mismatch or |
|---|---|---|---|---|
| | Green A | Green B | difference | difference |
| Red | Decay | Decay | between Red | between Red |
| Decay | Rate | Rate | and Green A | and Green B |
| Rate | (ms) | (ms) | (ms) | (ms) |
| 2.85 | 0.52 | 0.09 | 2.33 | 2.76 |
| 3.9 | 0.52 | 0.09 | 3.38 | 3.81 |
| 4.95 | 0.52 | 0.09 | 4.43 | 4.86 |

The difference in the decay rates between the red phosphor material at 50 wt % and the green phosphor material at 50 wt % is shown in Table 5. The difference in the decay rates between the red phosphor material and Green A and the difference in the decay rates between the red phosphor material and Green B are all below 7, which reduces display lag and blurring.

This written description uses examples to disclose the invention, including the best mode, and also to enable any person skilled in the art to practice the invention, including making and using any devices or systems and performing any incorporated methods. The patentable scope of the invention is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal languages of the claims.

1. A phosphor composition comprises a red phosphor material having a red decay rate and a green phosphor material having a green decay rate, wherein the red phosphor material comprises a Mn⁴⁺ doped phosphor of formula I
AₓMF_{y}:Mn⁴⁺ (I),
and a Eu³⁺ doped uranium phosphor, wherein a difference between the red decay rate and the green decay rate is no more than 7 ms, and wherein A is Li, Na, K, Rb, Cs, or a combination thereof; M is Si, Ge, Sn, Ti, Zr, Al, Ga, In, Sc, Hf, Y, La, Nb, Ta, Bi, Gd, or a combination thereof; x is an absolute value of a charge of the MF_{y} ion; and y is 5, 6 or 7.

2. The phosphor composition according to claim 1, wherein the Mn⁴⁺ doped phosphor is selected from the group consisting of: K₂(SiF₆):Mn⁴⁺, K₂(TiF₆):Mn⁴⁺, K₂(SnF₆):Mn⁴⁺, Cs₂(TiF₆):Mn⁴⁺, Rb₂(TiF₆):Mn⁴⁺, Cs₂(SiF₆):Mn⁴⁺, Rb₂(SiF₆):Mn⁴⁺, Na₂(TiF₆):Mn⁴⁺, Na₂(SiF₆):Mn⁴⁺, Na₂(ZrF₆):Mn⁴⁺, K₃(ZrF₇):Mn⁴⁺, K₃(BiF₇):Mn⁴⁺, K₃(YF₇):Mn⁴⁺, K₃(LaF₇):Mn⁴⁺, K₃(GdF₇):Mn⁴⁺, K₃(NbF₇):Mn⁴⁺, and K₃(TaF₇):Mn⁴⁺.

3. The phosphor composition according to claim 1, wherein the Mn⁴⁺ doped phosphor has a Mn loading or Mn % of at least 1 wt %.

4. (canceled)

5. The phosphor composition according to claim 1, wherein the Mn⁴⁺ doped phosphor comprises a surface coating, and the surface coating comprises a metal fluoride, wherein the metal fluoride is selected from the group consisting of MgF₂, CaF₂, SrF₂. BaF₂, AgF, ZnF₂, AlF₃ and a combination thereof.

6. (canceled)

7. The phosphor composition according to claim 1, wherein the Eu³⁺ doped uranium phosphor is selected from the group consisting of:
(i) a Eu³⁺ doped uranium phosphor having formula IIA
[Ba_{1-a-b}SrₐCa_{b}]ₓ[Mg,Zn]_{y}(UO₂)_{z}([P,V)]O₄)_{2(x+y+z)/3}:Eu³⁺ (IIA)
wherein 0≤a≤1, 0≤b≤1, 0.75≤x≤1.25, 0.75≤y≤1.25, 0.75≤z≤1.25;
(ii) a Eu³⁺ doped uranium phosphor having formula IIB
[Ba_{1-a-b}SrₐCa_{b}]ₓ[Mg,Zn]_{y}(UO₂)_{z}([P,V)]O₄)_{2(x+y+z)/3}:Eu³⁺ and A (IIB)
wherein 0≤a≤1, 0≤b≤1, 0.75≤x≤1.25, 0.75≤y≤1.25, 0.75≤z≤1.25 and A is Li⁺, Na⁺, K⁺, Rb⁺, Cs⁺, or mixtures thereof;
(iii) a Eu³⁺ doped uranium phosphor having formula IIIA
[Ba_{1-a-b}SrₐCa_{b}]ₚ(UO₂)_{q}[P,V]ᵣO_{(2p+2q+5r)/2}:Eu³⁺ (IIIA)
wherein 0≤a≤1, 0≤b≤1, 2.5≤p<3.5, 1.75≤q≤2.25, 3.5≤r≤4.5;
(iv) a Eu³⁺ doped uranium phosphor having formula IIIB
[Ba_{1-a-b}SrₐCa_{b}]ₚ(UO₂)_{q}[P,V]ᵣO_{(2p+2q+5r)/2}:Eu³⁺ and A (IIIB)
wherein 0≤a≤1, 0≤b≤1, 2.5≤p≤3.5, 1.75≤q≤2.25, 3.5≤r≤4.5 and A is Li⁺, Na⁺, K⁺, Rb⁺, Cs⁺, or mixtures thereof; and
(v) a Eu³⁺ doped uranium phosphor having formula IV
A₂UO₂ [P,V]₂O₇:Eu³⁺ (IV)
wherein A is Li, Na, K, Rb, Cs, or a combination thereof.

8. The phosphor composition according to claim 1, wherein the Eu³⁺ doped uranium phosphor is selected from the group consisting of: BaMgUO₂(PO₄)₂:Eu³⁺; BaZnUO₂(PO₄)₂:Eu³⁺; BaMgUO₂(PO₄)₂:Eu³⁺ and Li⁺; BaMgUO₂(PO₄)₂:Eu³⁺ and Na⁺; BaMgUO₂(PO₄)₂:Eu³⁺ and K⁺; BaMgUO₂(PO₄)₂:Eu³⁺ and Rb⁺; BaMgUO₂(PO₄)₂:Eu³⁺ and Cs⁺; BaZnUO₂(PO₄)₂:Eu³⁺ and Li⁺, BaZnUO₂(PO₄)₂:Eu³⁺ and Na⁺; BaZnUO₂(PO₄)₂:Eu³⁺ and K⁺; BaZnUO₂(PO₄)₂:Eu³⁺ and Rb⁺; BaZnUO₂(PO₄)₂:Eu³⁺ and Cs⁺; Ba₃(PO₄)₂(UO₂)₂P₂O₇:Eu³⁺; Ba₃(PO₄)₂(UO₂)₂P₂O₇:Eu³⁺ and Li⁺; Ba₃(PO₄)₂(UO₂)₂P₂O₇:Eu³⁺ and Na⁺; Ba₃(PO₄)₂(UO₂)₂P₂O₇:Eu³⁺ and K⁺Ba₃(PO₄)₂(UO₂)₂P₂O₇:Eu³⁺ and Rb⁺; Ba₃(PO₄)₂(UO₂)₂P₂O₇:Eu³⁺ and Cs⁺; Ba₃(PO₄)₂(UO₂)₂V₂O₇:Eu³⁺; Ba₃(PO₄)₂(UO₂)₂V₂O₇:Eu³⁺ and Li⁺; Ba₃(PO₄)₂(UO₂)₂V₂O₇:Eu³⁺ and Na⁺; Ba₃(PO₄)₂(UO₂)₂V₂O₇:Eu³⁺ and K⁺; Ba₃(PO₄)₂(UO₂)₂V₂O₇:Eu³⁺ and Rb⁺; Ba₃(PO₄)₂(UO₂)₂V₂O₇:Eu³⁺ and Cs⁺; γ-Ba₂UO₂(PO₄)₂:Eu³⁺; γ-Ba₂UO₂(PO₄)₂:Eu³⁺ and Li⁺; γ-Ba₂UO₂(PO₄)₂:Eu³⁺ and Na⁺; γ-Ba₂UO₂(PO₄)₂:Eu³⁺ and K⁺; γ-Ba₂UO₂(PO₄)₂:Eu³⁺ and Rb⁺; and γ-Ba₂UO₂(PO₄)₂:Eu³⁺ and Cs⁺; Na₂UO₂P₂O₇:Eu³⁺, K₂UO₂P₂O₇:Eu³⁺ and mixtures thereof.

9. The phosphor composition according to claim 1, wherein the red phosphor material comprises Na₂UO₂P₂O₇:Eu³⁺ and either Na₂SiF₆:Mn⁴⁺ or K₂SiF₆:Mn⁴⁺.

10. The phosphor composition according to claim 1, wherein the green phosphor material comprises a green-emitting phosphor selected from the group consisting of:
(i) a green-emitting phosphor having formula V
[Ba_{1-a-b}SrₐCa_{b}]ₓ[Mg,Zn]_{y}(UO₂)_{z}([P,V]O₄)_{2(x+y+z)/3} (V);
(ii) a green-emitting phosphor having formula VI
[Ba_{1-a-b}SrₐCa_{b}]ₚ(UO₂)_{q}[P,V]ᵣO_{(2p+2q+5r)/2} (VI);
(iii) a green-emitting phosphor having formula VII
A₂UO₂ [P,V]₂O₇ (VII);
(iv) a green-emitting phosphor having formula VIII
A₄UO₂([P,V]O₄)₂ (VIII); and
(v) a green-emitting phosphor having formula IX
AUO₂([P,V]O₃)₃ (IX)
wherein 0≤a≤1, 0≤b≤1, 0.75≤x≤1.25, 0.75≤y≤1.25, 0.75≤z≤1.25; 2.5≤p≤3.5, 1.75≤q≤2.25, 3.5≤r≤4.5 and A is Li, Na, K, Rb, Cs, or a combination thereof.

11. The phosphor composition according to claim 1, wherein the green phosphor material comprises a green-emitting phosphor selected from the group consisting of: Ba₃(PO₄)₂(UO₂)₂P₂O₇, Ba₃(PO₄)₂(UO₂)₂V₂O₇, gamma γ-Ba₂UO₂(PO₄)₂, BaMgUO₂(PO₄)₂, BaZnUO₂(PO₄)₂, Na₂UO₂P₂O₇, K₂UO₂P₂O₇, Rb₂UO₂P₂O₇, Cs₂UO₂P₂O₇, K₄UO₂(PO₄)₂, K₄UO₂(VO₄)₂, NaUO₂P₃O₉, and combinations thereof.

12. The phosphor composition according to claim 1, wherein the red phosphor material comprises Na₂UO₂P₂O₇:Eu³⁺ and either K₂SiF₆:Mn⁴⁺ or Na₂SiF₆:Mn⁴⁺ and the green phosphor material comprises BaZnUO₂(PO₄)₂ or γ-Ba₂UO₂(PO₄)₂.

13. The phosphor composition according to claim 1 further comprising one or more other luminescent materials.

14. The phosphor composition according to claim 13, wherein the one or more other luminescent material comprises an additional phosphor selected from the group consisting of: [Y,Gd,Lu,Tb]₃[Al,Ga]₅O₁₂:Ce³⁺, β-SiAlON:Eu²⁺, [Sr,Ca,Ba][Ga,Al]₂S₄:Eu²⁺, [Li,Ca]α-SiAlON:Eu²⁺, [Ba,Sr,Ca]₂Si₅N₈:Eu²⁺, [Ca,Sr] AlSiN₃:Eu²⁺, [Ba,Sr,Ca]LiAl₃N₄:Eu²⁺, [Sr,Ca,Mg]S:Eu²⁺, and [Ba,Sr,Ca]₂Si₂O₄:Eu²⁺.

15. The phosphor composition according to claim 13, wherein the one or more other luminescent material comprises at least one of electroluminescent polymers, phosphorescent dye, a quantum dot material, or scattering particles.

16-18. (canceled)

19. The phosphor composition according to claim 10, wherein the Mn⁴⁺ doped phosphor, the Eu³⁺ doped uranium phosphor and the green-emitting phosphor are in particulate form comprising a monodisperse population of particles having a particle size distribution comprising a D50 particle size from about 0.1 μm to about 15 μm.

20. A device comprising an LED light source optically coupled and/or radiationally connected to a phosphor composition, wherein the phosphor composition includes a red phosphor material having a red decay rate and a green phosphor material having a green decay rate, wherein the red phosphor material includes a Mn⁴⁺ doped phosphor of formula I,
AₓMF_{y}:Mn⁴⁺ (I),
and a Eu³⁺ doped uranium phosphor, wherein a difference between the red decay rate and the green decay rate is no more than 7 ms, and wherein A is Li, Na, K, Rb, Cs, or a combination thereof; M is Si, Ge, Sn, Ti, Zr, Al, Ga, In, Sc, Hf, Y, La, Nb, Ta, Bi, Gd, or a combination thereof; x is an absolute value of a charge of the MF_{y} ion; and y is 5, 6 or 7.

21. (canceled)

22. The device according to claim 20, wherein the Mn⁴⁺ doped phosphor is selected from the group consisting of: K₂(SiF₆):Mn⁴⁺, K₂(TiF₆):Mn⁴⁺, K₂(SnF₆):Mn⁴⁺, Cs₂(TiF₆):Mn⁴⁺, Rb₂(TiF₆):Mn⁴⁺, Cs₂(SiF₆):Mn⁴⁺, Rb₂(SiF₆):Mn⁴⁺, Na₂(TiF₆):Mn⁴⁺, Na₂(SiF₆):Mn⁴⁺, Na₂(ZrF₆):Mn⁴⁺, K₃(ZrF₇):Mn⁴⁺, K₃(BiF₇):Mn⁴⁺, K₃(YF₇):Mn⁴⁺, K₃(LaF₇):Mn⁴⁺, K₃(GdF₇):Mn⁴⁺, K₃(NbF₇):Mn⁴⁺, and K₃(TaF₇):Mn⁴⁺ and the Eu³⁺ doped uranium phosphor is selected from the group consisting of:
(i) a Eu³⁺ doped uranium phosphor having formula IIA
[Ba_{1-a-b}SrₐCa_{b}]ₓ[Mg,Zn]_{y}(UO₂)_{z}([P,V)]O₄)_{2(x+y+z)/3}:Eu³⁺ (IIA)
wherein 0≤a≤1. 0≤b≤1, 0.75≤x≤1.25, 0.75≤y≤1.25, 0.75≤z≤1.25;
(ii) a Eu³⁺ doped uranium phosphor having formula IIB
[Ba_{1-a-b}SrₐCa_{b}]ₓ[Mg,Zn]_{y}(UO₂)_{z}([P,V)]O₄)_{2(x+y+z)/3}:Eu³⁺ and A (IIB)
wherein 0≤a≤1, 0≤b≤1, 0.75≤x≤1.25, 0.75≤y≤1.25, 0.75≤z≤1.25 and A is Li⁺, Na⁺, K⁺, Rb⁺, Cs⁺, or mixtures thereof;
(iii) a Eu³⁺ doped uranium phosphor having formula IIIA
[Ba_{1-a-b}SrₐCa_{b}]ₚ(UO₂)_{q}[P,V]ᵣO_{(2p+2q+5r)/2}:Eu³⁺ (IIIA)
wherein 0≤a≤1, 0≤b≤1.2.5≤p≤3.5. 1.75≤q≤2.25. 3.5≤r≤4.5; and
(iv) a Eu³⁺ doped uranium phosphor having formula IIIB
[Ba_{1-a-b}SrₐCa_{b}]ₚ(UO₂)_{q}[P,V]ᵣO_{(2p+2q+5r)/2}:Eu³⁺ and A (IIIB)
wherein 0≤a≤1, 0≤b≤1, 2.5≤p≤3.5, 1.75≤q≤2.25, 3.5≤r≤4.5 and A is Li⁺, Na⁺, K⁺, Rb⁺, Cs⁺, or mixtures thereof; and
(v) a Eu³⁺ doped uranium phosphor having formula IV
A₂UO₂[P,V]₂O₇:Eu³⁺ (IV)
wherein A is Li, Na, K, Rb, Cs, or a combination thereof.

23-25. (canceled)

26. The device according to claim 20, wherein the green phosphor material comprises a green-emitting phosphor selected from the group consisting of:
(i) a green-emitting phosphor having formula V
[Ba_{1-a-b}SrₐCa_{b}]ₓ[Mg,Zn]_{y}(UO₂)_{z}([P,V]O₄)_{2(x+y+z)/3} (V);
(ii) a green-emitting phosphor having formula VI
[Ba_{1-a-b}SrₐCa_{b}]ₚ(UO₂)_{q}[P,V]ᵣO_{(2p+2q+5r)/2} (VI);
(iii) a green-emitting phosphor having formula VII
A₂UO₂[P,V]₂O₇ (VII);
(iv) a green-emitting phosphor having formula VIII
A₄UO₂([P,V]O₄)₂ (VIII); and
(v) a green-emitting phosphor having formula IX
AUO₂([P,V]O₃)₃ (IX)
wherein 0≤a≤1, 0≤b≤1, 0.75≤x≤1.25, 0.75≤y≤1.25, 0.75≤z≤1.25; 2.5≤p≤3.5, 1.75≤q≤2.25, 3.5≤r≤4.5 and A is Li, Na, K, Rb, Cs, or a combination thereof.

27-30. (canceled)

31. The device according to claim 20, wherein the phosphor composition is in a form of a film and is located remotely from the LED light source.

32. (canceled)

33. A lighting apparatus, a backlight apparatus, a display apparatus, or a self-emissive display comprising the device of claim 20.

34-36. (canceled)

37. The device according to claim 20, wherein the device is a television, a mobile phone, a computer monitor, a laptop, a tablet, or an automotive display.

38-45. (canceled)
